(19) United States
(12) Patent Application Publication
(10) Pub. No.: US 2025/0373241 A1
(43) Pub. Date: Dec. 4, 2025

(54) Electronic Power Switch with internal Over-Current Protection and galvanically isolated Current Sensing

(71) Applicant: Infineon Technologies AG, Neubiberg (DE)

(72) Inventors: Cristian IONASCU, Villach (AT); Christian DJELASSI-TSCHECK, Villach (AT); Thomas HAFNER, Magdalensberg (AT); Andre MOURRIER, Manosque (FR)

(21) Appl. No.: 19/195,179

(22) Filed: Apr. 30, 2025

(30) Foreign Application Priority Data
May 31, 2024 (DE) 102024115214.1

(51) Int. Cl. H03K 17/082; H03K 3/037

(52) U.S. Cl. CPC H03K 17/0822; H03K 3/037

(57) ABSTRACT

A circuit includes a power transistor with a first and a second load electrode and a line connected to the first or the second load electrode and configured to carry a load current that causes a magnetic field around the line. The circuit further includes a magnetic field sensor arranged adjacent to the line to sense the magnetic field and provide a current sense signal, which represents the load current. The circuit further includes a protection circuit including a comparator, a latch, and a first electronic switch, wherein the comparator is configured to signal, at its output, that the current-sense signal exceeds a first threshold value. The latch is set based on an output signal of the comparator, and the first electronic switch is coupled to a control electrode of the power transistor and configured to discharge the control electrode when the latch is set to switch the power transistor off.

### TECHNICAL FIELD

This disclosure relates to the field of electronic power switches, in particular to a power device with an integrated over-current protection and galvanically isolated current sensing.

### BACKGROUND

Electronic Switches are meanwhile ubiquitous in various areas of technology. Usually, one or more transistors are integrated in a conventional chip package without additional (logic or other auxiliary) circuitry. Various different types of transistors may be used in electronic switches, namely metal-oxide-semiconductor (MOS) field effect transistors (FETs), insulated-gate bipolar transistors (IGBTs), Silicon Carbide MOSFETs (SiC-FETs), bipolar junction transistors (in particular Darlington pairs), and so on.

Electronic switches with a single transistors therefore have three terminals, namely a drain/collector terminal, a source/emitter terminal, and a gate/base terminal. Some electronic switches may have a fourth terminal connected to an integrated diode which can be used as temperature sensor. In contrast, so-called smart switches do include various additional circuitry (e.g. a serial communication interface, current-limitation, over-temperature protection, current sensing functions, etc.) and therefore need a separate power supply. Obviously, smart switches are significantly more complex and need more terminals (e.g. chip pins).

In many applications the electronics has to be designed such that a safe operation of the electronic switches is guaranteed. The so-called safe operation area (SOA) of an electronic device is usually defined in terms of maximum ratings for temperature and load current. If normal electronic switches are used the over-current and over-temperature protection has to be provided by an external control or driver circuit. To simplify the circuit design process it may be desirable to have electronic switches which ensure operation within the SOA without increasing the number of pins (which would be the case if normal electronic switches were replaced by smart switches).

### SUMMARY

The embodiments described herein relate to a circuit that can be used in an electronic switch which provides an over-current protection without needing additional supply pins. The additional circuitry, which provides the over-current protection is supplied via an input terminal (e.g. gate/base terminal) and/or via a load terminal (drain/collector) terminal.

In one embodiment, the circuit includes a power transistor, which has a first and a second load electrode, and a line connected to the first or the second load electrode and configured to carry a load current of the power transistor, when it is switched on, wherein the load current causes a magnetic field around the line. The circuit further includes a magnetic field sensor arranged adjacent to the line to sense the magnetic field and configured to provide a current sense signal, which represents the load current. Furthermore, the circuit includes a protection circuit including a comparator, a latch, and a first electronic switch, wherein the comparator is configured to signal, at its output, that the current-sense signal exceeds a first threshold value. The latch is configured to be set based on an output signal of the comparator, and the first electronic switch is coupled to a control electrode of the power transistor and configured to discharge the control electrode when the latch is set to switch the power transistor off.

### BRIEF DESCRIPTION OF THE DRAWINGS

The embodiments can be better understood with reference to the following drawings and descriptions. The components in the figures are not necessarily to scale; instead emphasis is placed upon illustrating the underlying principles. In the figures, like reference numerals designate corresponding parts. In the drawings:

FIG. 1 illustrates one example of how an electronic switch can be used.

FIG. 2 illustrates one embodiment of an electronic switch with three chip terminals and integrated over-current protection.

FIG. 3 illustrates one exemplary implementation of the circuit of FIG. 2.

FIG. 4 illustrates a modification/enhancement of the example of FIG. 3.

FIG. 5 illustrates a modification of the examiner of FIG. 4, which allows an external circuit such as the gate driver to sense an over-current situation.

FIG. 6 illustrates the encapsulation of an electronic switch of FIG. 2-4 in a chip package.

FIG. 7 illustrates the example of FIG. 4 with an additional serial communication interface.

FIG. 8 illustrates the example of FIG. 4 with an additional temperature sensor.

FIGS. 9 and 10 are modifications of the example of FIG. 5 with a split gate.

### DETAILED DESCRIPTION

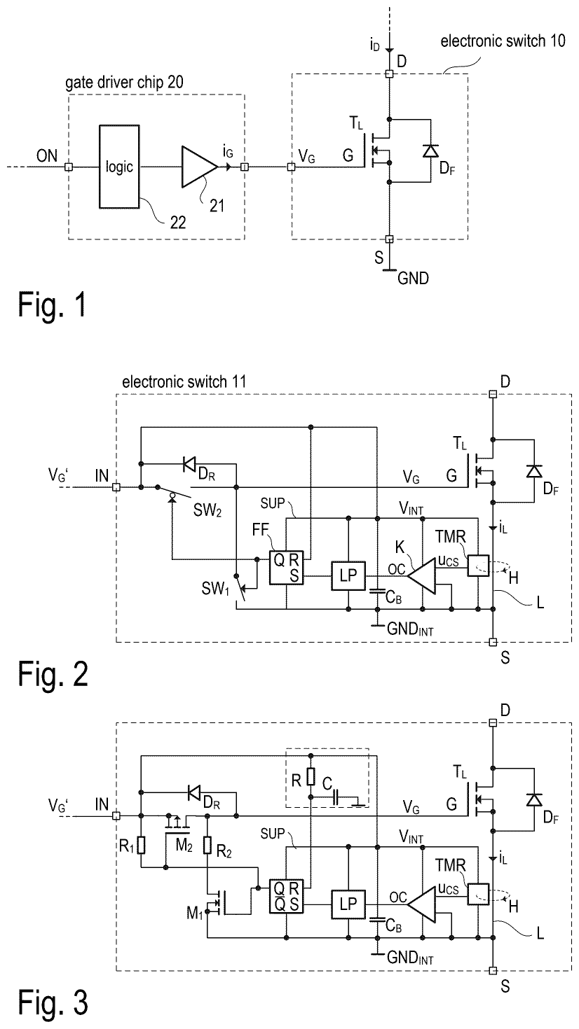

FIG. 1 illustrates one example of how a (conventional) electronic switch 10 can be used, e.g. in connection with a dedicated driver circuit 20. The electronic switch 10 may comprise a standard chip package such as a LFPAK package which is a de-facto industry standard for power devices. It is understood that any other type of chip package can be used and that different chip manufacturers use different names for the chip packages. Both, chip packages for through-hole mounting as well as surface mounting may be used.

Usually, the chip packages have more than three physical contacts (e.g. pins). However, two or more chip contacts may be bonded to the same electrode/terminal on the semiconductor chip so that the (load) current is distributed over two or more chip contacts. This reduces the current density in the chip contacts and reduces the on-resistance of the electronic switch. In the depicted example, the transistor T_{L} is connected in a low-side configuration, which means that it is connected between ground potential (or a low-side supply voltage) and the electric load (not shown in FIG. 1). As shown in FIG. 1, the transistor T_{L} may be an n-channel MOSFET and, therefore, the three chip contacts D, S, and G, are connected to the drain electrode, the source electrode and the gate electrode, respectively. AS mentioned above, any other transistor type (e.g. IGBT, SiC-FET, bipolar transistors in Darlington configuration, etc.) may be used.

In the example of FIG. 1, the illustration of the gate driver chips 20 is simplified. In the depicted example, the gate driver 20 includes a logic circuit 22 that is configured to receive a logic signal as input signal at an input terminal ON. The gate driver further includes an output stage 21 which generates the gate current i_{G} in response to a switching signal provided by the logic circuit. The logic circuit may, for example, include a galvanic isolation (realized, e.g. by integrated coreless transformers or an opto-coupler). Suitable gate driver devices are commercially available and are thus not discussed herein in more detail. An over-current protection is not provided in the example in FIG. 1.

FIG. 2 illustrates an example of a three-terminal device 11, which can replace the electronic switch 10 of FIG. 1 without having to modify the rest of the circuit. The power device 11 is an electronic switch with an integrated transistor T_{L} (like in the example of FIG. 1) and with additional circuitry that provides an over-current protection. In contrast to conventional smart switches, the power device 11 does not have extra supply terminals (chip contacts) for receiving a supply voltage for the over-current protection circuit (and further circuitry). Like in the example of FIG. 1 the load terminals (drain/collector and source/emitter) are denoted as “D” and “S”. The control terminal, which is connected to the gate/base electrode of the transistor T_{L} via a switch SW₂, is labelled “IN”. That is, when the switch SW₂ is closed, the voltage V_{G} at the input terminal (control terminal) is directly applied to the gate electrode of transistor T_{L} (or base electrode in case of a bipolar transistor). In some embodiments, the switch SW₂ may be omitted and the control terminal IN directly connected to the gate/base of the transistor T_{L}. That is, the switch SW₂ is optional. However, it may be useful to avoid overloading the gate driver output (connected to the control terminal IN) when the over-current protection is active.

As can be seen from FIG. 2, a line L connects to the chip terminal S and one of the load electrodes (the source electrode in the depicted example) of the transistor T_{L}. The line L may be implemented in a metallization layer of the semiconductor chip, in which the transistor T_{L} is integrated; it carries the load current i_{L} (when the transistor T_{L} is on), and the load current i_{L} causes a magnetic field H to form around the line L. The magnetic field strength is proportional to the load current i_{L} passing through the line L.

To enable current sensing, a magnetic field sensor (denoted as TMR in the example of FIG. 2) is arranged adjacent to the line L. The magnetic field sensor is configured to sense the magnetic field strength H (at the sensor position) and to provide a current sense signal u_{CS} which represents the load current i_{L}. In accordance with the embodiments described herein the magnetic field sensor may be a tunnel magneto-resistance (TMR) sensor that generates an output voltage u_{CS} which is substantially proportional to the magnetic field strength at the sensor position. As the magnetic field strength H is proportional to the load current i_{L}, the sensor output voltage u_{CS} can be regarded as current sense signal. A TMR sensor has a relatively high sensitivity (as compared to other types of magnetic field sensors) and has a substantially linear characteristic. Dependent on the application, other types of magnetic field sensors (e.g. a giant magneto-resistance (GMR) sensor or a Hall sensor) may be used instead of a TMR sensor.

The current sense signal u_{CS} is an input signal for an over-current protection circuit, which includes a comparator K, a latch F, and an electronic switch SW₁. The comparator K is configured to signal, at its output, that the current sense signal u_{CS} exceeds a first threshold value u₁ (e.g. the comparator signals whether the over-condition u_{CS}>i₁ is fulfilled), and the latch FF is set based on the output signal OC of the comparator K. That is, the latch FF “stores” the overcurrent condition and signals it at its output Q. According to the present example, the latch FF may be an SR-latch (also referred to as RS flip-flop). The electronic switch SW₁ (not to be confused with SW₂) is coupled to the control electrode G of the power transistor T_{L} (i.e. the base electrode in case of a MOSFET) and configured to discharge the control electrode G, when the latch FF is set, to switch off the power transistor T_{L}.

As can be seen from FIG. 2, a filter circuit may be coupled between the output of the comparator K and the set input S of the latch F. The filter circuit LP may suppress transient voltage spikes at the input of the latch that may lead to an undesired switching of the latch F. In one implementation the filter circuit is a passive low-pass filter (RC filter).

As mentioned, the electronic switch SW₂ couples the control/input terminal IN with the gate electrode G of the power transistor T_{L}. The electronic switch SW₂ is configured to disconnect the input terminal IN from the date electrode G when the latch FF is set (and thus the switch SW1 is closed). Both switches SW₁ and SW₂ switch the opposite way, i.e. SW₂ is open when SW₁ is closed, and vice versa. The switch SW₂ may be omitted and replaced by a direct line between the chip terminal IN and the gate electrode G, dependent on the implementation of the gate driver providing the voltage V_{G} at the input terminal IN.

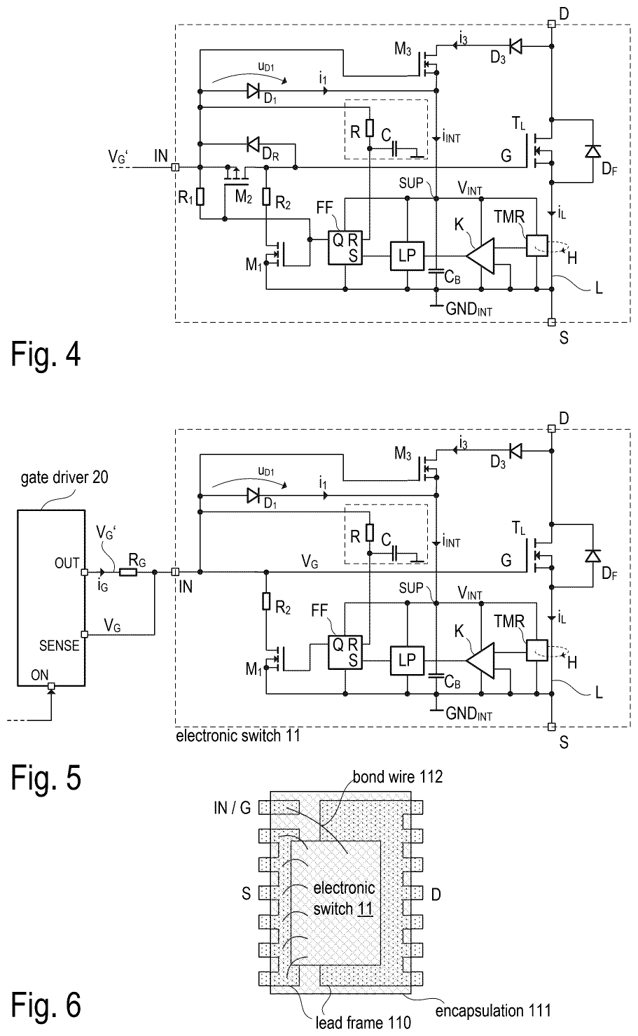

A supply circuit provides an internal supply voltage V_{IN} that may supply the over-current protection circuit (i.e. the latch FF and the comparator K) as well as the magnetic field sensor TMR. The supply circuit is connected to the input/control terminal IN and, in one embodiment, basically includes a buffer capacitor C_{B} which can be charged via the input terminal, i.e. by the gate driver (not shown in FIG. 2, see FIG. 1) connected to the input terminal IN. The buffer capacitor provides the internal supply voltage V_{IN} between an internal supply node SUP and an internal ground node GND_{INT}. A diode (not shown in FIG. 2, see FIG. 4) may be connected between the input terminal IN and the internal supply node SUP so that the diode prevents a discharging of the capacitor C_{B} via the input terminal IN (when the voltage V_{G} applied to the input terminal IN is low). In the depicted example, the internal ground node GND_{INT} is connected to the source electrode of the power transistor T_{L} (emitter electrode in case of a bipolar transistor).

The latch FF is set based on the output OC of the comparator K. The reset of the latch FF may be accomplished by a reset circuit that is configured to reset the latch FF based on a level (high or low) of the input signal V_{G}′ applied at the input/control terminal IN. Although the input voltage V_{G}′ (which equals the gate voltage V_{G} if the switch SW₂ is closed) is not necessary a logic signal, it has, nevertheless, either a low level or a high level form the perspective of the latch F. That is, if V_{G}′<V_{TH}, the latch FF “sees” a low level at its reset input and, if V_{G}′>V_{TH}, the latch FF “sees” a high level at its reset input. V_{TH} is a threshold, wherein there may be different thresholds, i.e. a hysteresis, for the transitions low-to-high and high-to-low. In the examples shown herein, the latch FF has a dominant set input, i.e. the latch FF will be set upon a high level at the set input S even if there is also a high level at the reset input R. The high level at the set input S overrides a high level at the reset input. A dominant set input is, however, not necessary but a latch without a dominant set input would require additional logic circuitry.

In the example shown in FIG. 2, the input terminal IN is directly connected with the reset input R of the latch. In this specific case, the reset circuit is only a conductive line by which the input signal is supplied to the reset input of the latch. In another example, the reset circuit may include a passive low-pass filter coupled between the input terminal IN and a reset input of the latch F.

The example of FIG. 3 is basically the same as the circuit of FIG. 2. However, FIG. 3 shows one exemplary implementation of the switches SW₁ and SW₂. Further, the circuit of FIG. 3 shows the above-mentioned low-pass filter included in the reset circuit, which is coupled between the input terminal IN and the reset input R of the latch F. In the depicted example, the low-pass filter is a passive first-order RC filter. The switch SW₁ is an n-channel MOSFET M₁ and the switch SW₂ is a p-channel MOSFET M₁. The gate of the transistor M₁ is connected to the non-inverting output Q of the latch F. That is, transistor M₁ switches on when the latch FF is set. The gate of the transistor M₂ is also connected to the non-inverting output Q of the latch F. As transistor M₂ is a p-channel MOSFET, it switches off when the latch FF is set.

When the comparator K detects an over-current situation, in which the current sense signal u_{CS} is above a maximum value uₘₐₓ, the latch FF is set and the transistor M₁ is closed. As a result, transistor M₁ provides a low-ohmic current patch from the power transistor's gate electrode G the source electrode S; the gate-source capacitance is thus discharged via transistor M₁ and the power transistor T_{L} is switched off. The discharge current through the transistor M₁ is limited by the optional resistor R₂, which may have a relatively low resistance.

During such an over-current situation, the gate driver (not shown in FIG. 3) still applies the input voltage V_{G}′ to the input terminal IN. To avoid overloading the output of the gate driver, it may be desired to disconnect the input terminal IN from the gate electrode G of the power transistor T_{L} by opening the transistor M₂. However, dependent on the implementation of the gate driver, transistor M₂ may be omitted. In the present example a resistor R₁ is connected between source and gate electrode of transistor M₂. This resistor R₁ is optional but, dependent on the actual implementation, may be needed to determining a defined off-state of M₂ (i.e. gate-source-voltage of M₂ being zero). The diode D_{R} is coupled in parallel to the transistor M₂ and allows a discharging of the gate electrode G through the input terminal IN when the gate driver switches off the power transistor T_{L} (by generating a gate voltage V_{G}′ with a low voltage level). The diode D_{R} may be the intrinsic body diode of transistor M₂. Apart from transistors M₁ and M₂ and the RC filter between the input terminal IN and the reset input R of the latch, the circuit of FIG. 3 is the same as in FIG. 2 and reference is made to the respective description above.

The example of FIG. 4 is a modification/enhancement of the example of FIG. 3, wherein the only difference between FIGS. 3 and 4 is in the implementation of the supply circuit which provides the internal supply voltage V_{INT}. The modification of FIG. 4 addresses the problem that the current consumption of the TMR sensor may be too high to take the sensor current alone from the input terminal IN. In the previous examples, the internal current consumption i_{INT} of the overcurrent protection circuit has to be provided by the gate driver output stage (not shown in FIG. 4). The internal current consumption i_{INT} of the overcurrent protection circuit is mainly determined by the sensor current of the TMR sensor and may be in the range of a few milli-amperes (e.g. around 2 mA).

According to FIG. 4, the internal supply node SUP is connected to the input/control terminal IN via diode D₁ and to the power transistor's drain electrode D via the drain-source path of a further transistor M₃, whose gate is also connected to the input terminal IN. The transistor M₃ is not operated as a switch but rather as a controllable current source. Assuming the operating current i_{INT} consumed by the overcurrent protection circuit and the TMR sensor is low, the current i_{INT} will be taken only from the input terminal IN and flow through diode D₁ (diode current i₁=i_{INT}). Transistor M₃ is off and the transistor current i₃ will be substantially zero. The forward voltage u_{D1} of the is proportional to the logarithm of the ratio i₁/i_{S} wherein i_{S} is the reverse leakage current of the diode (u_{D1}˜ln(i₁/i_{S})). When the current i_{INT} increases, the forward voltage u_{D1} increases and transistor M₃ becomes conductive and the transistor current i₃ can contribute to the operating current i_{INT}, i.e. i_{INT}=i₁+i₃. The transistor characteristic curve and the diode characteristic curves can be matched to each other according to the requirements of the application so that the transistor M₃ automatically becomes active if the operating current i_{INT} is high enough to activate the transistor M₃. The current i₃ is taken from the drain terminal D, while the voltage V_{INT} is determined by the input voltage V_{G}′ (gate voltage) applied at the input terminal IN.

As can be seen form FIG. 4, the transistor M₃, which is part of the supply circuit providing the internal supply voltage V_{INT}, is operated as a source follower, i.e. the voltage at the source of transistor M₃ (which determines the internal supply voltage V_{INT}) basically “follows” the gate voltage V_{G}′ of transistor M₃. The diode D₃ coupled between the drain of transistor M₃ and the drain terminal D of the power transistor may block a reverse current in some situations.

FIG. 5 illustrates a modification of the examiner of FIG. 4, which allows an external circuit such as the gate driver to sense an over-current situation. The electronic switches of FIGS. 4 and 5 are basically identical except for transistor M₂ (switch SW₂) which is omitted in the example of FIG. 5. Without the transistor M₂ disconnecting the input terminal IN from the power transistor's gate in an over-current situation (when the latch FF is set) allows an external circuit such as the gate driver 20 to sense the over-current situation by monitoring the voltage V_{G} (gate voltage of power transistor T_{L}) at the terminal IN.

During normal operation (no over-current), the voltage V_{G}′ output by the gate driver at terminal OUT and the actual gate voltage V_{G} at the power transistor's gate electrode are substantially equal when the transistor T_{L} is on (after the transient switch-on process). The voltage drop across the gate resistance R_{G} is negligible and the gate driver “sees” the gate voltage V_{G} at its sense input, which has a very high input resistance and thus draws only a negligible current. In contrast, in an over-current situation (when the latch FF is set), the transistor M₁ pulls the gate voltage V_{G} down towards the source voltage, which is the voltage at the internal ground GND_{INT}. This voltage drop from V_{G}′ to internal ground can be sensed by the gate driver 20 at the sense input SENSE without needing any additional sense pin. The gate driver 20 may, for example, signal the over-current situation to a superordinate controller (not shown in FIG. 5) and/or set the voltage V_{G}′ output at the terminal OUT to zero. As explained above, the next switch-on (by setting the voltage V_{G}′ to a sufficiently high level) will reset the latch FF and switch the power transistor T_{L} on again.

FIG. 6 illustrates the encapsulation of an electronic switch of FIG. 2-4 in a chip package. The semiconductor die with the electronic switch 11 is mounted on a lead frame 110 that has (only) three terminals IN, S, and D, wherein the load terminals S and D have a plurality of pins to distribute the load current. The source terminal and the input terminal are is connected with respective bond pads on the semiconductor die. The drain terminal is on the back-side of the semiconductor die, which is directly bonded to the lead frame 11. The encapsulation 111 (composed of mold compound) is denoted by the numeral 112. At his point it is again emphasized that the device of FIGS. 2-5 is a three-terminal device that does not need any extra supply terminals for providing a voltage supply to the protection circuit and the current sense circuit integrated in the semiconductor die in addition to the power transistor T_{L}.

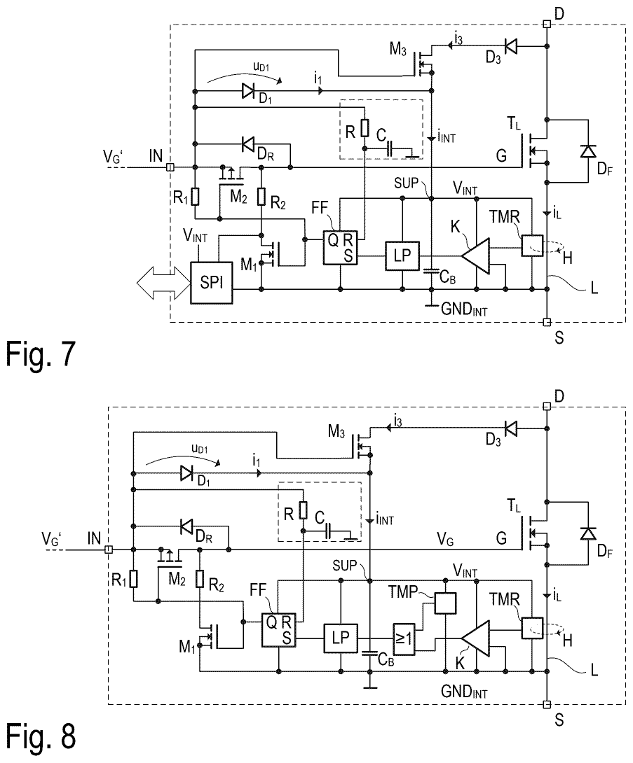

FIG. 7 illustrates the example of FIG. 4 with an additional serial communication interface. The communication interface is also supplied by the internal supply voltage V_{INT}. It may be any conventional communication interphase such as the commonly used Serial Peripheral Interface (SPI). However, any other types of digital communication may be used (I2C bus, UART, etc.). The communication interface allows an external controller (e.g. a programmable microcontroller) to communicate with the electronic switch and to obtain status information which may include the detection of an over-current situation. It is understood, that other embodiments may be modified/enhanced to communicate any useful information (e.g. the current sense signal, a temperature value, etc.) via the digital communication interface.

FIG. 8 illustrates the example of FIG. 4 with an additional temperature sensor TMP. In one embodiment, the temperature sensor may comprise a current source configured to generate a sensor current that passes through a pn-junction. The temperature-dependent forward voltage of the pn-junction may be used as a temperature sense signal. In the depicted example, the temperature sensor outputs a logic signal that indicates whether the temperature is above a threshold value (representing the allowed maximum temperature). The output signals of the temperature sensor TMP and the comparator K are combined by an OR-gate whose output is connected to the set input of the latch F. Accordingly, the latch FF is set when either an over-current situation or an over-temperature situation (i.e. measured being above a threshold) is detected.

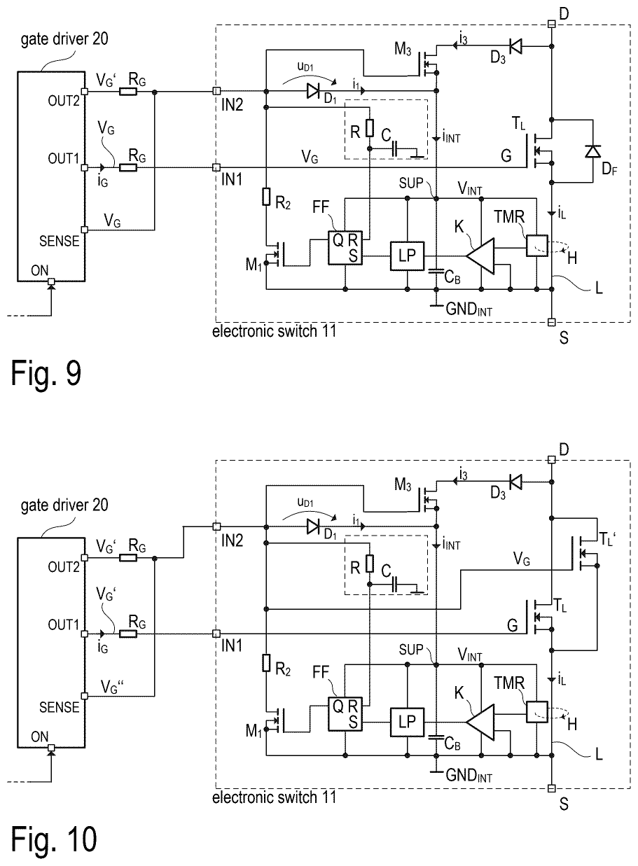

FIGS. 9 and 10 are modifications of the example of FIG. 5 with a split gate. The example of FIGS. 5 and 9 only differ in that, in FIG. 9, the gate electrode of the power transistor T_{L} is connected to a separate input terminal IN1, wherein the gate electrode of transistor M₃ and the reset circuit for latch FF are connected to the input terminal IN2. If the input terminals IN1 and IN2 were connected to each other, the electronic switch of FIG. 9 would behave the same way as the electronic switch in FIG. 5.

In the example of FIG. 9, the power transistor T_{L} can be switched on by the gate driver 20 outputting a sufficiently high gate voltage to both inputs IN1 and IN2. If an over-current situation is detected by comparator K, the latch FF is set in the same way as in the circuits of FIG. 2-5. The over-current situation can be sensed by the gate driver 20 as the voltage V_{G}″ received at the sense input SENSE of the gate driver 20 is low (pulled down by transistor M₁ towards ground potential). When the gate driver 20 “sees” (detects) the over-current situation, it can set the gate voltage V_{G}, which is output at terminal OUT1, to zero to switch the power transistor off. The protection circuit (sensor TMR, comparator K, latch F, transistor M₁) functions the same way as in the previous example of FIG. 5 but the final decision to switch off the power transistor T_{L} is made by the gate driver 20. Therefore, in this example, the protection circuit may be regarded as a monitoring circuit.

The power transistor T_{L} may be composed of a plurality of transistor cells arranged in a cell array. The drain-source-paths of transistor cells are connected in series to distribute the load current over the transistor cells. In the examples of FIG. 1-9 the gate electrodes of the transistor cells are also interconnected to that all transistor cells are switched on and off simultaneously as they see the same gate signal. In the example of FIG. 10 the gates of a first fraction (e.g. 80 percent) of the transistor cells are connected to input terminal IN1, and the gates of a section fraction (e.g. 20 percent) of the transistor cells are connected to input terminal IN2. That is the majority of transistor cells form a first transistor T_{L} and the remaining transistor cells form a second transistor T_{L}′.

The example of FIG. 10 may be regarded as a combination of the examples of FIGS. 5 and 9. The smaller power transistor T_{L}′ (the one with the fewer transistor cells) is protected by the protection circuit like the power transistor in FIG. 5, while the larger power transistor T_{L}′ (the one with the fewer transistor cells) needs to be protected by the gate driver 20, which is able to sense the over-current condition (or an over-temperature condition if an additional temperature sensor is provided) like explained above with reference to FIGS. 5 and 9.

Commonly smart switches often make use of a so-called “sense transistor” which is operated in the same operating point as the power transistor but has a smaller active area so that the transistor current passing through the sense transistor is (significantly smaller but) proportional to the load current passing through the power transistor. According to the approach presented herein, even when using a split gate as shown in FIGS. 9 and 10, the full load current is measured by the TMR sensor (and not a small fraction of the load current as it would be the case when using a sense transistor). Therefore, the TMR sensor allows current measurement with superior accuracy as compared to the sense transistor concept.

Finally, it is noted that the features of the exemplary embodiments described above can be combined to obtain further embodiments. For example, the temperature sensor TMP shown in FIG. 8 may be used in connection with any other embodiment described herein. Similarly, the digital communication interface shown in FIG. 7 may be used in connection with any other embodiment described herein to enable digital communication of useful sensor and status information to an external circuit (e.g. microcontroller or the like). Moreover, in all examples, the supply circuit may, or may not, include the transistor M₃ discussed with reference to FIG. 4. In examples without the transistor M₃, the total supply current i_{INT} is drawn from the input terminal and thus has to be provided by the gate driver (see FIG. 3).

The embodiments described herein are briefly summarized below. It is understood that the following is not an exhaustive list of embodiments but rather an exemplary summary. One embodiment relates to a circuit that includes a power transistor (see FIGS. 2-5 and 7-10, transistor T_{L} and/or T_{L}′), which has a first and a second load electrode (e.g. drain and source electrode in case of a MOSFET). The circuit further includes an electric line (e.g. a strip line in the chip's metallization layer), which is connected to the first or the second load electrode and configured to carry a load current of the power transistor, when it is switched on. The load current causes a magnetic field around the line, and a magnetic field sensor is arranged adjacent to the line to sense the magnetic field and configured to provide a current sense signal, which represents the load current. The magnetic field sensor is integrated in the same chip or chip package as the rest of the circuit. Furthermore, the circuit includes a protection circuit including a comparator, a latch, and a first electronic switch, wherein the comparator is configured to signal, at its output, that the current-sense signal exceeds a first threshold value. The latch is configured to be set based on an output signal of the comparator, and the first electronic switch is coupled to a control electrode (e.g. the gate electrode in case of a MOSFET) of the power transistor and configured to discharge the control electrode when the latch is set to switch the power transistor off.

In one embodiment, the circuit includes a supply circuit that is connected to a first input terminal and configured to provide an internal supply voltage V_{IN} between an internal supply node and an internal ground node (see FIGS. 2-5 and 7-10, nodes SUP and GND_{INT}). In a simple example, the supply circuit basically includes a buffer capacitor, which can be charged via the first input terminal. The internal ground node may be connected to the second load electrode (e.g. source electrode in case of a MOSFET) of the power transistor. The buffer capacitor may be connected between the internal supply node and the internal ground node.

In one embodiment, the protection circuit further includes a second electronic switch (see FIGS. 2-4 and 7-8, switch SW₂, M₂) connected between the first input terminal and the control electrode of the power transistor and configured to disconnect the first input terminal from the control electrode, when the latch is set. In some embodiment, the second electronic switch is not needed (see, e.g., FIGS. 5 and 9-10).

In one embodiment, the circuit includes a reset circuit that is configured to reset the latch based on a logic level of an input signal applied at the first input terminal. The reset circuit may be, for example, an passive low-pass filter coupled between the first input terminal and a reset input of the latch. In one embodiment the latch has a dominant set input. This is not necessarily the case but this feature simplifies the circuit design. Furthermore, a filter circuit may be coupled between the output of the comparator and a set input of the latch (see, e.g., FIGS. 2-5 and 7-10, low-pass filter LP).

In some embodiments, the circuit is included in a chip package which has only three separate terminals and no dedicated supply terminals (see, e.g. FIG. 6). Several physical leads/pins may of the chip may, however, be interconnected to distribute the load current. The interconnected leads/pins, nevertheless, form one terminal.

In one embodiment, the mentioned supply circuit includes a further transistor (see, e.g. FIGS. 4-5 and 710, transistor M₃) whose control electrode (gate in case of a MOS transistor) is connected to the first input terminal and whose load current path is coupled between the internal supply node SUP and the first load electrode (the drain electrode in case of a MOSFET) of the power transistor. This further transistor may be a field effect transistor configured as source follower or a bipolar transistor configured as emitter follower, wherein the gate (or base) is connected to the first input terminal. The internal supply voltage therefore follows an input voltage received at the first input terminal.

In one example (see, e.g. FIG. 9), the power transistor has a control electrode coupled to a separate (second) input terminal. In one example, the power transistor may be a split gate transistor (see, e.g. FIG. 10) which has a first and a second control electrode, wherein the first control electrode is coupled to the first input terminal and the second control electrode is coupled to the second input terminal.

Although the invention has been illustrated and described with respect to one or more implementations, alterations and/or modifications may be made to the illustrated examples without departing from the spirit and scope of the appended claims. In particular regard to the various functions performed by the above described components or structures (units, assemblies, devices, circuits, systems, etc.), the terms (including a reference to a “means”) used to describe such components are intended to correspond—unless otherwise indicated—to any component or structure, which performs the specified function of the described component (e.g., that is functionally equivalent), even though not structurally equivalent to the disclosed structure, which performs the function in the herein illustrated exemplary implementations of the invention.

1. A circuit comprising:
a power transistor (T_{L}) having a first and a second load electrode;
a line (L) connected to the first or the second load electrode and configured to carry a load current (i_{L}) when the power transistor (T_{L}) is on, the load current (i_{L}) causing a magnetic field (H) around the line (L);
a magnetic field sensor arranged adjacent to the line (L) to sense the magnetic field (H) and configured to provide a current sense signal (u_{CS}) which represents the load current (i_{L});
a protection circuit including a comparator (K), a latch (F), and a first electronic switch (SW₁, M₁),
wherein the comparator (K) is configured to signal, at its output, that the current sense signal (u_{CS}) exceeds a first threshold value (u₁),
wherein the latch (F) is configured to be set based on an output signal (OC) of the comparator (K), and
wherein the first electronic switch (SW₁, M₁) is coupled to a control electrode (G) of the power transistor (T_{L}) and configured to discharge the control electrode (G) when the latch (F) is set to switch the power transistor (T_{L}) off.

2. The circuit of claim 1, further comprising,
a supply circuit (C_{B}) that is connected to a first input terminal (IN, IN2) and configured to provide an internal supply voltage (V_{IN}) between an internal supply node and an internal ground node (GND_{INT}).

3. The circuit of claim 1, wherein the protection circuit further includes:
a second electronic switch (SW₂, M₂) connected between a first input terminal (IN, IN2) and the control electrode (G) of the power transistor (T_{L}) and configured to disconnect the first input terminal (IN, IN2) and the control electrode (G) when the latch (F) is set.

4. The circuit of claim 3, further comprising,
a supply circuit (C_{B}) that is connected to the first input terminal (IN, IN2) and configured to provide an internal supply voltage (V_{IN}) between an internal supply node and an internal ground node (GND_{INT}).

5. The circuit of claim 4,
wherein the internal ground node (GND_{INT}) is connected to the second load electrode of the power transistor (T_{L}), and/or
wherein the supply circuit includes a buffer capacitor connected between (C_{B}) the internal supply node and the internal ground node (GND_{INT}).

6. The circuit of of claim 1, further comprising:
a reset circuit configured to reset the latch (F) based on a logic level of an input signal applied at the first input terminal (IN, IN2).

7. The circuit of claim 6,
wherein the reset circuit is an passive low-pass filter coupled between the first input terminal (IN, IN2) and a reset input of the latch (F).

8. The circuit of claim 1,
wherein the latch (F) has a dominant set input.

9. The circuit of claim 1,
wherein a filter circuit is coupled between the output of the comparator (K) and a set input of the latch (F).

10. The circuit of claim 1,
wherein the circuit is included in a chip package which has only three separate terminals and/or no dedicated supply terminals.

11. The circuit of claim 1, further comprising:
a supply circuit that includes a further transistor (M₃) whose control electrode is connected to the first input terminal (IN, IN2) and whose load current path is coupled between an internal supply node (SUP) and the first load electrode (D) of the power transistor (T_{L}).

12. The circuit of claim 11,
wherein the further transistor (M₃) is a field effect transistor configured as source follower or a bipolar transistor configured as emitter follower.

13. The circuit of claim 11, wherein the internal supply voltage follows an input voltage (V_{G}′) received at the first input terminal (IN, IN2).

14. The circuit of claim 1,
wherein the power transistor (T_{L}) has a control electrode coupled to a second input terminal (IN2).

15. The circuit of claim 1,
wherein the power transistor is a split gate transistor (T_{L}, T_{L}′) which has a first and a second control electrode, the first control electrode being coupled to a first input terminal (IN1) and the second control electrode being coupled to a second input terminal (IN2).
